(19) United States
(12) Patent Application Publication
(10) Pub. No.: US 2005/0231922 A1
(43) Pub. Date: Oct. 20, 2005

(54) Functional printed circuit board module with an embedded chip

(76) Inventor: Jung-Chien Chang, Taoyuan Hsien (TW)

Correspondence Address: HERSHKOVITZ & ASSOCIATES, 1725 I STREET NW, SUITE 300, WASHINGTON, DC, 20006, US

(21) Appl. No.: 10/825,662

(22) Filed: Apr. 16, 2004

(51) Int. Cl. H05K 1/00

(52) U.S. Cl. 361/750

(57) ABSTRACT

A functional PCB module in accordance with the present invention comprises a frame having at least one chip recess, at least one chip mounted in the chip recess, at least one printed circuit formed on one side of the frame and material filling the chip recess. The chip has terminals interconnected to the printed circuit. Since the chip is embedded in the frame to complete the functional PCB module, the functional PCB module is effectively thinner. Furthermore, two or more functional PCB modules are easily combined to form a multi-layer PCB by using a vacuum compression process.

### BACKGROUND OF THE INVENTION

1. Field of the Invention

The present invention relates to a functional printed circuit board, and more particularly to a functional printed circuit board with an embedded chip.

2. Description of Related Art

Many types of printed circuit boards (PCB) have been developed such as single-sided PCBs, double-sided PCB, multi-layer PCBs, etc. In principle, the PCB is prepared with multiple pads on which electronic components are soldered to complete a functional PCB.

With reference to FIG. 7, a conventional functional PCB (not numbered) comprises a PCB (50), at least one IC (60) and multiple passive elements (70) and has a total thickness. The PCB (50) has a top (not numbered), multiple pads (51) and a thickness. The pads (51) have a thickness. The IC (60) and passive elements (70) have heights and are soldered on the pads (51). In general, the IC (60) is composed of at least one chip (61), a lead frame (not shown) and an encapsulate (not shown) so the height of the IC (60) is larger than that of other passive elements (70). Therefore, the total thickness of the functional PCB (50) is a sum of the heights of IC (60), the pads (51) and the PCB (50). Although current semiconductor package technology and PCB fabrication technology are able to fabricate thin profile products, the total thickness of the functional PCB is not effectively minimized.

The total thickness of the functional PCB is hard to decrease effectively since the IC or passive elements are mounted on the top of the PCB. That is, to decrease the total thickness of the functional PCB effectively the connecting method between the PCB and the IC and passive elements has to be changed.

To overcome the shortcomings, the present invention provides a functional PCB having an embedded chip to mitigate and obviate the aforementioned problems

### SUMMARY OF THE INVENTION

The main objective of the invention is to provide a functional printed circuit board (PCB) module having an embedded chip to effectively decrease a functional PCB module's total thickness.

In accordance with the present invention, at least one chip is embedded in a frame. At least one printed circuit is formed on one side of the frame and is interconnected to a chip in the frame. That is, the chip is integrated in the frame so the functional PCB module thickness is thinner than the conventional functional PCB.

Another objective of the invention is to provide various PCB module configurations such as single-sided, single layer PCBs, double-sided, single layer PCBs, multi-layer PCBs, etc.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional side plan view of a first embodiment of a functional PCB module in accordance with the present invention;

FIG. 2 is a cross sectional side plan view of a second embodiment of a functional PCB module in accordance with the present invention;

FIG. 3 is a cross sectional side plan view of a third embodiment of a functional PCB module in accordance with the present invention;

FIG. 4 is a cross sectional side plan view of a fourth embodiment of a functional PCB module in accordance with the present invention;

FIG. 5 is a cross sectional side plan view of a fifth embodiment of a functional PCB module in accordance with the present invention;

FIG. 6 is a cross sectional side plan view of a sixth embodiment of a functional PCB module in accordance with the present invention; and

FIG. 7 is a side plan view of a conventional functional PCB in accordance with the prior art.

### DETAILED DESCRIPTION OF THE PREFERRED EMBODIMENT

A functional printed circuit board (PCB) module in accordance with the present invention integrates a chip into a PCB to decrease the PCB module total thickness.

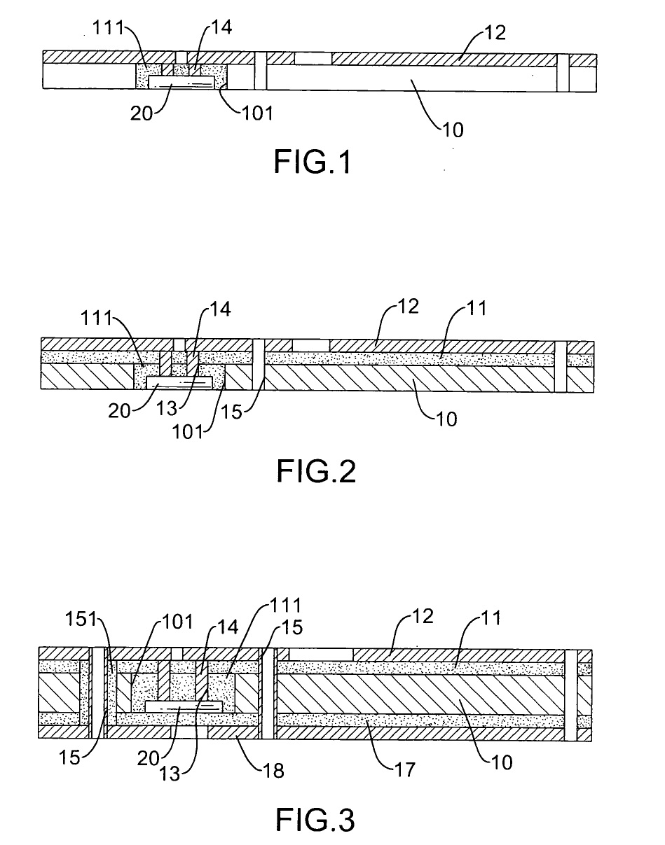

With reference to FIG. 1, the functional printed circuit board (PCB) module in accordance with the present invention comprises a frame (10), at least one chip (20), at least one printed circuit (12) and insulation material (111). The frame (10) has two sides (not numbered) and at least one chip recess (101). The chips (20) correspond respectively to the chip recesses (101), and a chip (20) is mounted in the each chip recess (101). One printed circuit (12) is formed on one side of the frame (10) and connects to the chip (20). Each chip recess (101) is filled with insulation material (111) and encapsulates the chip (20), so the chip (20) is embedded in the frame (10). Therefore, the present invention provides a functional PCB module having an embedded chip.

A first embodiment of the functional printed circuit board (PCB) module in accordance with the present invention comprises a frame (10), a printed circuit (12), one chip (20) and insulation material (111). The frame (10) has two opposite two sides (not numbered), is nonmetallic and has one chip recess (101). The printed circuit (12) is formed on one side. The chip (20) has a top face (not numbered) and multiple terminals (not numbered) and is mounted in the chip recess (101). The terminals are formed on the top face and face upward toward the printed circuit (12). The printed circuit (12) on the frame (10) is connected to the chip (20) in the chip recess (101), and the chip recess (101) is filled with insulation material (111).

With reference to FIG. 2, a second embodiment of a functional PCB module in accordance with the present invention is similar to the first embodiment, but the frame (10) is metallic and further includes an insulation layer (11).

The insulation layer (11) has multiple through holes (13) and multiple plugs (14) and is formed between the frame (10) and the printed circuit (12). The multiple through holes (13) correspond to the terminals of the chip (20) and are defined through the first insulation layer (11). Each plug (14) is formed in the corresponding through hole (13) to connect to the chip (20) and the printed circuit (12).

Further, if the metal frame (10) is connected to a ground and the printed circuit (12) has to be connected to the ground, at least one electroplate via (15) is formed through the printed circuit (12), the insulation layer (11) and the frame (10). The printed circuit (12) is connected to the ground through the electroplated via (15) and also has good heat dissipation.

The first and second embodiments apply to single-sided, and single-layer functional PCB modules.

With reference to FIG. 3, a third embodiment of a functional PCB module in accordance with the present invention is a double-sided, single-layer functional PCB module and comprises a frame (10), at least one chip (20), a first and second insulation layer (11, 17), a first and second printed circuit (12, 18), insulation material (111) and multiple vias (15). The at least one chip (20) has multiple terminals. The frame (10) has at least one chip recess (101) and two opposite sides (not numbered).

The first insulation layer (11) is formed on one side of the frame (10) and has multiple through holes (13) and plugs (14). The through holes (13) correspond to the chip (20) terminals, and the plugs (14) are formed respectively in the corresponding through holes (13). The first printed circuit (12) is formed on the first insulation layer (11). The second insulation layer (17) is formed on the other side of the frame (10), and the second printed circuit (18) is formed on the second insulation layer (17).

The multiple vias (15) are defined through the first printed circuit (12), the first insulation layer (11), the frame (10), the second insulation layer (17) and the second printed circuit (18) and selectively may have insulation wells (151). Thus, each via (15) electrically connects the first printed circuit (12) to the second printed circuit (18). Unless an insulation well (151) is implemented, the via (15) is also connected to the metal frame (10).

To insulate the via (15) from the metal frame (10), an insulation well (151) is formed around the selected via (15) between the first and second printed circuits (12, 17). Therefore, the via (15) is insulated from the metal frame (10) and is connected only to the first and second printed circuits (12, 18).

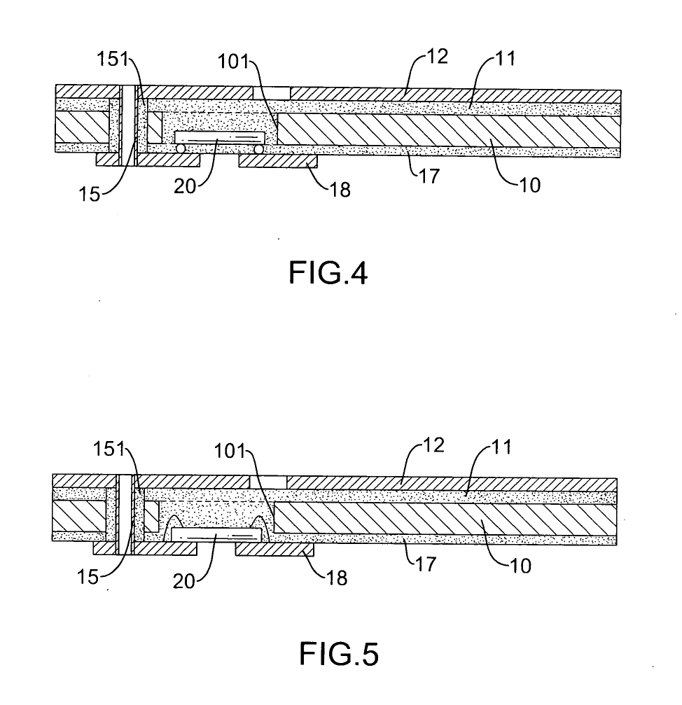

With reference to FIG. 4, a fourth embodiment of a functional PCB module in accordance with the present invention has another connection between the chip (20) and the first and second printed circuits (12, 18) that is different from the forgoing preferred embodiments.

The chip (20) has multiple solder bumps (21) is mounted in the chip recess (101) with the top face with terminals facing downward. The solder bumps (21) are formed respectively on the terminals on the chip (20). The solder bumps (21) are attached to the second printed circuit (18). Thus, the chip (20) is connected to the first printed circuit (12) through the via (15) that connects the first and second printed circuit (12, 18).

With reference to FIG. 5, a fifth embodiment of a functional PCB module in accordance with the present invention provides another connection between the chip (20) and the first and second printed circuits (12, 18). The chip (20) is mounted in the chip recess (101) with the top face and the terminals facing the first printed circuit (12). The terminals on the top face are connected to the second printed circuit (12) by wire bindings (not numbered) embedded in the insulating material (111) in the chip recess (101). Further connection of the chip (20) to the first printed circuit (12) is made through the via (15) between the first and second printed circuits (12, 18).

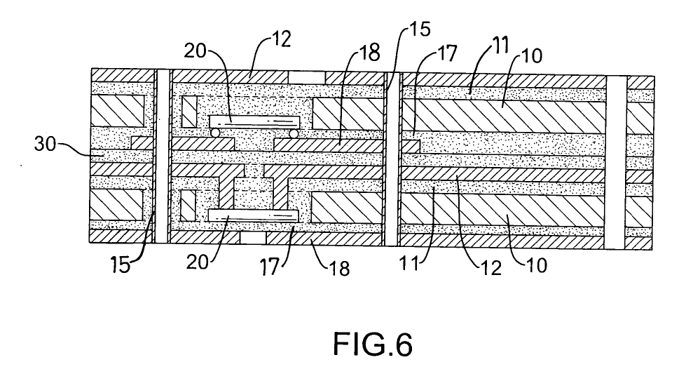

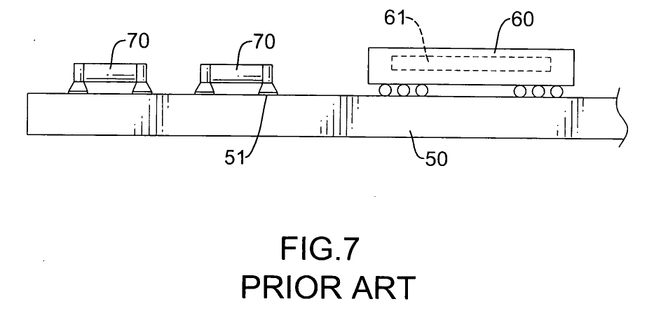

With further reference to FIG. 6, a sixth embodiment of a functional PCB module in accordance with the present invention is a multi-layer PCB that is a combination of any two or more of the forgoing preferred embodiments of the functional PCB module. A combination of the third and fourth embodiments has a fourth embodiment mounted on a third embodiment and a separation layer (30). The separation layer (30) is formed between the first printed circuit (12) of the third embodiment and the exposed second insulation layer (17) and the second printed circuit (18) of the fourth embodiment. The third and fourth embodiments are combined with a vacuum compression process.

The present invention provides a functional PCB module with an integrated chip so the chip is directly embedded in the PCB and is not packaged as an integrated circuit (IC) element. Therefore, the functional PCB module is thinner and is suitable for mounting in a tiny electronic product. Since the chip is not packaged and directly embedded in the PCB module, fabricating a functional PCB module is quicker and less expensive.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A functional printed circuit board (PCB) module having an embedded chip, the PCB module comprising:
a frame having two opposite sides and at least one chip recess defined in the frame;
a first printed circuit formed on one side of the frame and insulated from the frame;
at least one chip mounted in the at least one chip recess and connected to the first printed circuit, wherein the at least one chip has a top face, a bottom face and multiple terminals each of which is formed on the top face and connected to the first printed circuit; and
insulation material filling the at least one chip recess.

2. The functional PCB module as claimed in claim 1, wherein the frame is nonmetallic.

3. The functional PCB module as claimed in claim 1, wherein the frame is metal and further comprises a first insulation layer between the first printed circuit and the frame.

4. The functional PCB module as claimed in claim 3, wherein the first insulation layer has multiple through holes corresponding to the terminals defined through the first insulation layer and the insulation material in the at least one chip recesses; and
multiple plugs are formed respectively in corresponding through holes to connect the first printed circuit to the at least one chip.

5. The functional PCB module as claimed in claim 4 further comprising:
a second insulation layer formed on the other side of the frame;
a second printed circuit layer formed on the second insulation layer; and
multiple vias each of which has an outside and is formed through the first printed circuit, the first insulation layer, the frame, the second insulation layer and the second printed circuit to connect the first printed circuit to the second printed circuit.

6. The functional PCB module as claimed in claim 5, wherein an insulation well is formed around the outside of each via between the first insulation layer and the second insulation layer to insulate the via from the frame.

7. The functional PCB module as claimed in claim 3 further comprising:
a second insulation layer formed on the other side of the frame;
a second printed circuit layer formed on the second insulation layer; and
multiple vias each of which has an outside and is formed through the first printed circuit, the first insulation layer, the frame, the second insulation layer and the second printed circuit to connect the first printed circuit to the second printed circuit.

8. The functional PCB module as claimed in claim 7, wherein each chip has multiple solder bumps formed respectively on the terminals, and the solder bumps are connected to the second printed circuit.

9. The functional PCB module as claimed in claim 7, wherein the bottom face of each chip is attached to the second printed circuit, and the terminals of each chip are connected to the second printed circuit by wire bindings.

10. The functional PCB module as claimed in claim 2 further comprising:
a second printed circuit layer formed on the second insulation layer; and
multiple vias each of which has an outside and is formed through the first printed circuit, the frame and the second printed circuit to connect the first printed circuit to the second printed circuit.

11. The functional PCB module as claimed in claim 10, wherein an insulation well is formed around the outside of each via corresponding to the frame to insulate the via from the frame.

12. The functional PCB module as claimed in claim 11, wherein each chip has multiple solder bumps formed respectively on the terminals, and the solder bumps are connected to the second printed circuit.

13. The functional PCB module as claimed in claim 11, wherein the bottom face of each chip is mounted on the second printed circuit and the terminals of each chip are connected to the second printed circuit by wire binding.

14. A multi-layer functional PCB having embedded chips, combining at least two functional PCB modules and a separation layer between adjacent functional PCB modules, each functional PCB module comprising:
a frame having two opposite sides and at least one chip recess defined in the frame;
a first printed circuit formed on one of two opposite sides and insulated from the frame;
at least one chip mounted in the at least one chip recess and connected to the first printed circuit, wherein the at least one chip has a top face, a bottom face and multiple terminals formed on the top face and connected to the first printed circuit; and
insulation material filling the at least one chip recess.

15. The multi-layer functional PCB as claimed in claim 14, wherein each functional PCB module further comprises a second printed circuit formed on the other side of the frame and insulated from the frame; and
the multi-layer functional PCB further comprises multiple vias, each of which has an outside and is formed through adjacent functional PCB modules and the separation layers to connect the first and second printed circuits on the functional PCB modules.

16. The multi-layer functional PCB as claimed in claim 15, wherein the frames in the functional PCB modules are metal and each functional PCB module further comprises:
a first insulation layer between the first printed circuit and the frame; and
a second insulation layer between the second printed circuit and the frame.

17. The multi-layer functional PCB as claimed in claim 16, wherein one functional PCB module further comprises multiple through holes corresponding to the terminals, wherein the multiple through holes are defined through the first insulation layers and a plug mounted in each through hole.

18. The multi-layer functional PCB as claimed in claim 16, wherein each chip of one functional PCB module has solder bumps formed respectively on the terminals to connect the terminals to the second printed circuit.

19. The multi-layer functional PCB as claimed in claim 16, wherein the bottom face of each chip of one functional PCB module is mounted on the second printed circuit, and the terminals are connected to the second printed circuit by wire bindings.

20. The multi-layer functional PCB as claimed in claim 18, wherein the bottom face of each chip of another functional PCB module is mounted on the second printed circuit, and the terminals are connected to the second printed circuit by wire bindings.
